(19) United States
(12) Patent Application Publication
(10) Pub. No.: US 2022/0215145 A1
(43) Pub. Date: Jul. 7, 2022

(54) MACHINE LEARNING FOR RAPID AUTOMATIC COMPUTER-AIDED ENGINEERING MODELING

(71) Applicant: XITADEL CAE TECHNOLOGIES INDIA PVT. LTD., Karnataka (IN)

(72) Inventors: Prakash KRISHNASWAMY, Karnataka (IN); Umesh MALLIKARJUNAIAH, Karnataka (IN)

(73) Assignee: XITADEL CAE TECHNOLOGIES INDIA PVT. LTD., Karnataka (IN)

(21) Appl. No.: 17/613,136

(22) PCT Filed: May 19, 2020
(86) PCT No.: PCT/IB2020/054736

§ 371 Date: Nov. 22, 2021

(30) Foreign Application Priority Data
May 22, 2019 (IN) 201941020269

(51) Int. Cl. G06F 30/27; G06F 30/23; G06F 30/12; G06V 10/77; G06V 10/776; G06T 17/20; G06V 20/64

(52) U.S. Cl. CPC G06F 30/27; G06F 30/23; G06F 30/12; G06V 20/64; G06V 10/776; G06T 17/20; G06V 10/7715

(57) ABSTRACT

A memory stores a representation of geometric features of an object, a machine learning model configured to identify one or more feature families of features of the representation, and feature-specific parameters defining how to mesh the one or more feature families. A processor recognizes and classifies features of the representation into the feature families utilizing the machine learning model, applies feature-specific mesh parameters to the recognized and classified features of the representation, and generates a mesh of the representation in accordance with the feature-specific parameters.

### CROSS-REFERENCE TO RELATED APPLICATION

This application claims the benefit of Indian provisional application Serial No. 201941020269, filed on May 22, 2019, the disclosure of which is hereby incorporated in its entirety by reference herein.

### TECHNICAL FIELD

The present disclosure relates to aspects ofuse of machine learning for rapid automatic computer-aided engineering (CAE) modeling, for example, for use in the meshing of parts with complex features.

### BACKGROUND

A 3D object may be modeled as a computerized representation that describes the geometry and other aspects of the object. Computer-Aided Design (CAD) involves the application of computers to aid in the creation and modification of 3D CAD objects. Computer-Aided Engineering (CAE) starts with “meshing” the CAD geometry, assembling such meshes of different parts that constitute an assembly, modeling the connection between meshes, applying forces and boundary conditions to the model to aid in analysis, or optimization of the model. A mesh is a discretization of the modeled object into simpler elements shell or solid elements that includes triangles, quadrilaterals, hexahedral elements. Mesh generation is the practice of creating a mesh by performing a subdivision of the continuous geometric spaces of the modeled 3D object into discrete geometric and topological cells.

### SUMMARY

In one or more illustrative examples, a system for generating a finite element mesh, includes a memory configured to store a representation of geometric features of an object, a machine learning model configured to identify one or more feature families of features of the representation, and feature-specific parameters defining how to mesh the one or morefeature families; and a processor programmed to recognize and classify features of the representation into the feature families utilizing the machine learning model, apply feature-specific mesh parameters to the recognized and classified features of the representation, and generate a mesh of the representation in accordance with the feature-specific parameters.

In one or more illustrative examples, a method includes storing, to a memory, a representation of geometric features of an object, a machine learning model configured to identify one or more feature families of features of the representation, and feature-specific parameters defining how to mesh the one or more feature families; recognizing and classifying features of the representation into the feature families utilizing the machine learning model; applying feature-specific mesh parameters to the recognized and classified features of the representation; and generating a mesh of the representation in accordance with the feature-specific parameters.

In one or more illustrative examples, a non-transitory computer-readable medium includes instructions that, when executed by a processor, cause the processor to store, to a memory, a representation of geometric features of an object, a machine learning model configured to identify one or more feature families of features of the representation, and feature-specific parameters defining how to mesh the one or more feature families; recognize and classify features of the representation into the feature families utilizing the machine learning model; apply feature-specific mesh parameters to the recognized and classified features of the representation; and generate a mesh of the representation in accordance with the feature-specific parameters.

### BRIEF DESCRIPTION OF THE DRAWINGS

FIG. 1 illustrates an example block diagram of a process flow for the generation of a mesh by a CAE system using CAD data from a CAD system;

FIG. 2 illustrates an example block diagram of a system using machine learning for rapid automatic computer-aided engineering modeling;

FIG. 3 illustrates an example data flow diagram for the generation of an artificial intelligence (AI) model;

FIG. 4 illustrates an example data flow diagram for the creation of feature-specific settings;

FIG. 5 illustrates an example of meshes generated for three example features with different customer-specific settings;

FIG. 6 illustrates an example data flow diagram for the generation of a mesh from CAD data;

FIG. 7 illustrates an example process for the generation of an AI model;

FIG. 8 illustrates an example process for the generation of a mesh from CAD data in accordance with the AI model;

FIG. 9 illustrates an example rendering of a CAD file to be converted into a mesh;

FIG. 10 illustrates an example rendering of a CAD file highlighting features of the CAD file recognized by the AI model; and

FIG. 11 illustrates an example rendering of a mesh generated using feature-specific mesh parameters for the recognized features.

FIG. 12 illustrates an example of the automatic correction of quality specifications of the mesh;

FIG. 13 illustrates an example process for the automatic correction of quality specifications of a mesh;

FIG. 14 illustrates an example of additional different modeling algorithms that may be used to model feature families of CAD data into a mesh;

FIG. 15 illustrates an example process for the meshing of the feature families of CAD data 104 into the mesh;

FIG. 16 illustrates an example of identifying features or parts which are not needed for a specific simulation type;

FIG. 17 illustrates an example process for the meshing of CAD data into the mesh, while reconciling features to be ignored for the specific simulations to be performed;

FIG. 18 illustrates an example of thickness assignment performed using the CAE system;

FIG. 19 illustrates an example process for the automatic calculation of thickness for assignment to finite element of a mesh generated from CAD data;

FIG. 20 illustrates an example of components of different materials or manufacturing processes that may be converted into meshes;

FIG. 21 illustrates an example process for the meshing of CAD data into the mesh, while applying meshing algorithms according to material or manufacturing process;

FIG. 22 illustrates an example process for the retraining and use of an updated AI model for feature recognition and meshing;

FIG. 23 illustrates an example of identifying part assemblies from CAD data; and

FIG. 24 illustrates an example process for the meshing of CAD data into the mesh, while identifying locations for sensor placement.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

CAD models may be discretized and then used to simulate various aspects of the modeled object. To do so, the model must be converted into a mesh. Once converted into the mesh, a simulation phase may be performed using CAE simulation software. Some examples of simulation using the mesh include materials modeling, durability simulation, stiffness simulation, crash simulation, manufacturing simulation and optimization. Based on the simulation results, the model may be validated, or changes may be made to the model.

However, a challenge in the generation of meshes from CAD models is the time involved. In many cases, the meshing of parts may require hours or days of time expended in creating the mesh and ensuring that the created mesh meets with customer requirements. This may be due to the fact that certain features of the parts are to be meshed using specific meshing algorithms, but identification of the features during meshing may take a large amount of time.

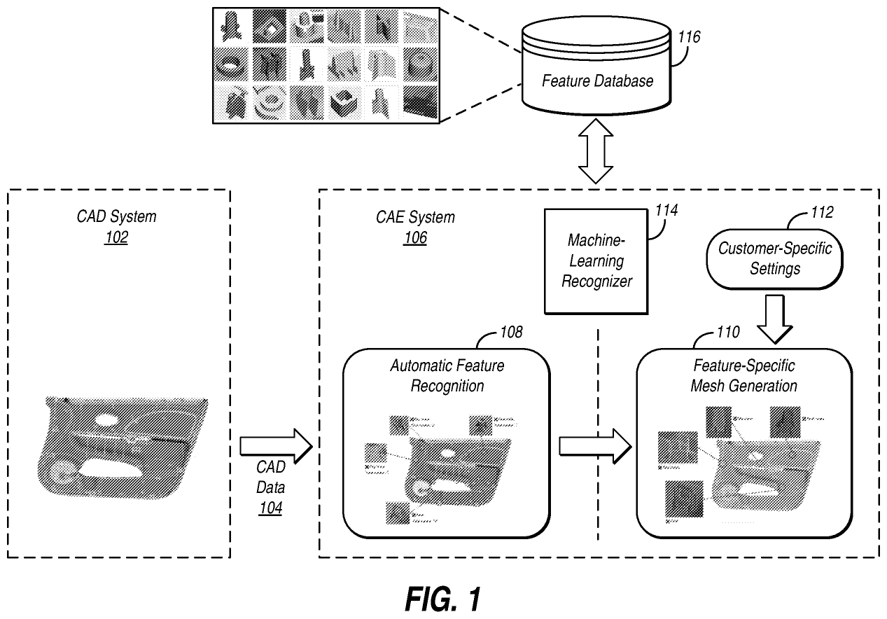

FIG. 1 illustrates an example block diagram of a process flow for the generation of a mesh by a CAE system 106 using CAD data 104 from a CAD system 102. As shown, the CAD system 102 is used by an operator to model one or more objects. In an example, CAD operator may utilize software such CATIA to perform the modeling. In this case, a door panel is illustrated, but this is merely one possibility. The CAD system 102 may generate the CAD data 104 based on the model. The CAD data 104 generally includes information with respect to lines and surfaces of the modeled objects. This CAD data 104 is then provided to the CAE system 106 for conversion into a mesh. First, the CAE system 102 performs automatic feature recognition 108 to identify features of the CAD data 104. Then, the CAE system performs feature-specific mesh generation 110 on the CAD data 104 to generate a mesh according to best practices of the customer, which are defined by customer-specific settings 112.

As explained in further detail below, the improved approach to generating the mesh from a CAD model includes the use of a machine-learning recognizer 114 for identification of features in the CAD data 104. The improved approach utilizes a previously-trained machine learning model to recognize and classify features of the mesh using training data including known features within families of features. Feature-specific meshing algorithms may then be associated with the families of features. The approach may additionally recognize and classify features of the representation into the feature families utilizing the machine-learning recognizer 114 and feature database 116, apply feature-specific meshing algorithms to the recognized and classified features of the representation, and generate a mesh of the representation in accordance with the feature-specific meshing algorithms. The CAE system 102 may further assign thicknesses to each element of the mesh based on the CAD data 104. Additionally, the CAE system 102 may create an assembly by connecting multiple CAE meshes into a single overall object. Once these steps are completed, the mesh may be exercised for crash, vibration, or other aspects. Further aspects of the disclosure are discussed in detail below.

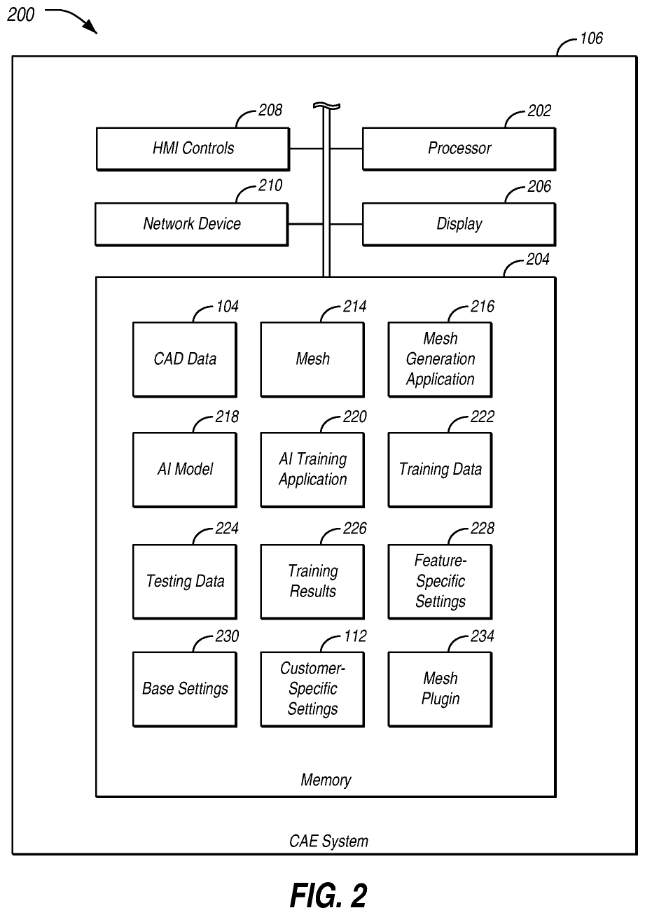

FIG. 2 illustrates an example block diagram of details of the CAE system 106 using machine learning for rapid automatic computer-aided engineering modeling. The CAE system 106 includes a processor 202 that is operatively connected to a memory 204, a display device 206, human-machine interface (HMI) controls 208, and a network device 210. CAD data 104 may be received to the CAE system 106 and provided to a mesh generation application 216 for conversion into a mesh 214. A mesh plugin 234 may be utilized by the mesh generation application 216 to recognize and classify features of the CAD data 104 into the feature families utilizing an AI model 218 and assign feature-specific meshing algorithms 228 to the recognized feature families. It should be noted that the CAB system 106 is merely an example, and CAE systems 106 having more, fewer, or differently arranged elements may also be used. As one example, the functionality of the mesh plugin 234 may be incorporated into the mesh generation application 216 in other examples.

In the CAE system 106, the processor 202 may include one or more integrated circuits that implement the functionality of a central processing unit (CPU) and/or graphics processing unit (GPU). In some examples, the processor 202 is a system on a chip (SoC) that integrates the functionality of the CPU and GPU. The SoC may optionally include other components such as, for example, the memory 204 and the network device 210 into a single integrated device. In other examples, the CPU and GPU are connected to each other via a peripheral connection device such as PCI express or another suitable peripheral data connection. In one example, the CPU is a commercially available central processing device that implements an instruction set such as one of the x86, ARM, Power, or MIPS instruction set families. Additionally, alternative embodiments of the processor 202 can include microcontrollers, application specific integrated circuits (ASICs), field programmable gate arrays (FPGAs), digital signal processors (DSPs), or any other suitable digital logic devices.

Regardless of the specifics, during operation, the processor 202 executes stored program instructions that are retrieved from the memory 204. The stored program instructions include software that controls the operation of the processor 202 to perform the operations described herein. The memory 204 may include both non-volatile memory and volatile memory devices. The non-volatile memory includes solid-state memories, such as NAND flash memory, magnetic and optical storage media, or any other suitable data storage device that retains data when the CAE system 106 is deactivated or loses electrical power. The volatile memory includes static and dynamic random-access memory (RAM) that stores program instructions and data during operation of the CAE system 106.

The GPU may include hardware and software for display of at least two-dimensional (2D) and optionally three-dimensional (3D) graphics to a display device 206. The display device 206 may include an electronic display screen, projector, printer, or any other suitable device that reproduces a graphical display. In some examples, the processor 202 executes software programs using the hardware functionality in the GPU to accelerate the performance of machine learning or other computing operations described herein.

The HMI controls 208 may include any of various devices that enable the CAE system 106 to receive control input. Examples of suitable input devices that receive human interface inputs may include keyboards, mice, trackballs, touchscreens, voice input devices, graphics tablets, and the like.

The network device 210 may include any of various devices that enable the CAE system 106 to send and/or receive data from external devices. Examples of suitable network devices 210 include a network adapter or peripheral interconnection device that receives data from another computer or external data storage device, which can be useful for receiving large sets of data in an efficient manner.

The CAD data 104 may refer to a computerized representation that describes the geometry and other aspects of an object to be simulated and/or manufactured. In an example, the CAD data 104 may include information indicative of vertices, edges, faces, polygons, and/or surfaces of the object. In another example, the CAD data 104 may further include material property data indicative of the materials of the object. The CAD data 104 may further include features such as stiffness, noise vibration harshness (NVH), crash, durability, and computational fluid dynamics (CFD) data. In some examples, the CAD data 104 may represent a set of separate parts, and the CAD data 104 may, accordingly, include assembly data indicative how to assemble the separate parts to create the object.

The CAD data 104 may include one or more features, which are individual elements of the object that may be included on a substrate from a library ofparts. As used herein, features generally refer to combinations of multiple different lower-level geometries that, in combination, form a higher-level construct. As some examples, these elements may be categorized into families of elements, such as heat stakes, clip towers, dog houses, and click fastener elements. As some other examples, these elements may be categorized into fbmilies such as nuts, bolts, molded rubber components, bushings, sleeves, seals, mounts, or bellows.

A family may include many different variations of the feature. For instance, a heat stake generally includes a tower element with a set of vanes connecting the tower element to the substrate of the object. Accordingly, the family of heat stakes may include many variations on this design, such as heat stakes having different numbers of ribs, different styles or shapes of ribs, different thicknesses, different heights, or connection with other features.

The mesh 214, or finite element mesh, refers to vertices, edges, and faces that use a polygonal representation, such as triangles and quadrilaterals, to define an object such as a 3D shape. Thus, the mesh 214 is a discretization of the CAD data 104. In general, the more polygons used to create the mesh 214 of the features, the less discretization error that occurs in the difference between the mesh 214 and the object described by the CAD data 104. However, the more polygons used, the larger the amount of storage and computing power that is required for use of the mesh 214.

The mesh generation application 216 includes instructions that, when executed by the processor 202 of the CAE system 106, cause the CAE system 106 to perform various processes and operations described herein. The mesh generation application 216 may be programmed to generate a mesh 214 representation of the object from the information of the CAD data 104. As some examples, the mesh generation application 216 may make use of techniques such as multi-block structured/mapped mesh generation, unstructured mesh generation, face clustering, a hybrid of these approaches, and so on to build a mesh 214 of the shapes represented by the CAD data 104.

The mesh generation application 216 may use various meshing algorithms to configure the generation of the mesh 214 from the CAD data 104. As some non-limiting examples, these meshing algorithms may specify how closely the mesh faces adhere to the shape of the object, the level of smoothness, and the density of the tessellation (e.g., the number of subdivisions) per dimension.

In artificial intelligence (AI) systems, model-based reasoning refers to an inference method that operates based on an AI model 218 of a worldview to be analyzed. Generally, the AI model 218 is trained to learn a function that provides a precise correlation between input values and output values. At runtime, an AI engine uses the knowledge encoded in the AI model 218 against observed data to derive conclusions such as a diagnosis or a prediction. One example AI engine may include the TensorFlow AI engine made available by Alphabet Inc. of Mountain View, Calif., although other machine learning systems may additionally or alternately be used. As discussed in detail herein, the AI model 218 may be configured to recognize and classify features of the CAD data 104 into the Feature families.

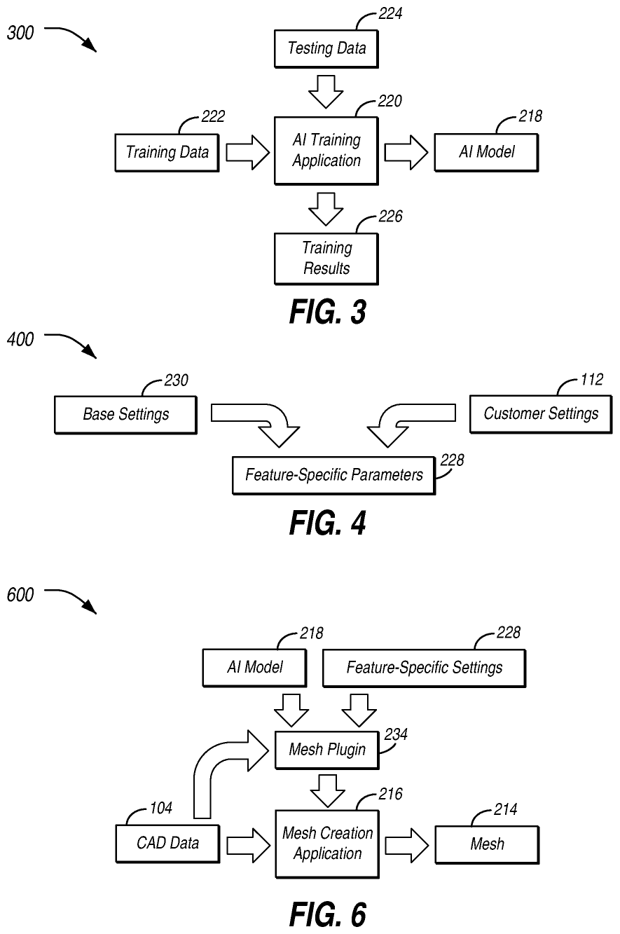

FIG. 3 illustrates an example data flow diagram 300 for the generation of an AI model 218. Referring to FIG. 3, and with continuing reference to FIG. 2, the AI model 218 may be trained by an AI training application 220 to recognize the features based on a set of training data 222. The training data 222 may include various variations of the features to be recognized by the AI model 218 as well as ground truth information indicative of what features are included in the training data 222 to be recognized.

The training data 222 may include data from many different features, based on CAD data 104 from one or more customers. The training data 222 may be stored to the feature database 116, in an example. As different customers may utilize different features, when a new customer is added, training data 222 including examples of that customer's features may be added to the training data 222 to improve the AI model 218 in recognition of those additional features. This additional data may include, for example, a new design of a feature for an existing customer, or a new feature that is not already recognized by the AI model 218. It should also be noted that while in some examples the features may be features of plastic models, in other examples the features may further include metal parts such as bolts, nuts, gears, connectors, or rubber parts such as gaskets.

The training data 222 may, in one example, include collections of 2D views or projections of features of models, where the views are taken as renderings of sample CAD data 104 at many different angles and distances. In such an example, the at model 218 may be trained to recognize the features in 2D form. Accordingly, when recognition is performed by the AI model 218, the recognition is performed in 2D form using 2D views or projections of the CAD data 104 to be converted into a mesh 214.

Testing data 224, which may be a subdivision of the training data 222 that is not used for training, may be used to validate the accuracy of the AI model 218 in recognizing feature of the CAD data 104. Through use of the testing data 224, the AI training application 220 may provide training results 226, which may be used to identify weaknesses in the AI model 218 or areas in which the AI model 218 should receive additional data to improve in its recognition of features in feature

It should be noted that the AI model 218 may include be trained based on training data 222 that is common across customers. This may allow for the AI training application 220 to take advantage of variations across a wide set of training data 222 in the formulation of the AI model 218. However, in some examples, customers may wish to have their data remain proprietary and not be shared in the generation of the AI model 218. In such instances, the AI model 218 for a customer may be created using proprietary training data 222, as well as whatever common training data 222 is available.

FIG. 4 illustrates an example data flow diagram 300 for the creation of feature-specific meshing algorithms 228. Referring to FIG. 4, and with continuing reference to FIG. 2, the feature-specific meshing algorithms 228 include meshing algorithms that may be used by the mesh generation application 216 to configure the generation of the mesh 214 from the CAD data 104. The feature-specific meshing algorithms 228 may include base settings 230, which may include industry-standard meshing algorithms for the generation of meshes 214 from CAD data 104.

The feature-specific meshing algorithms 228 may further include customer-specific settings 112, which may be specified by the specific customer to override the base settings 230 in instances where the customer has requirements that deviate from the base settings 230.

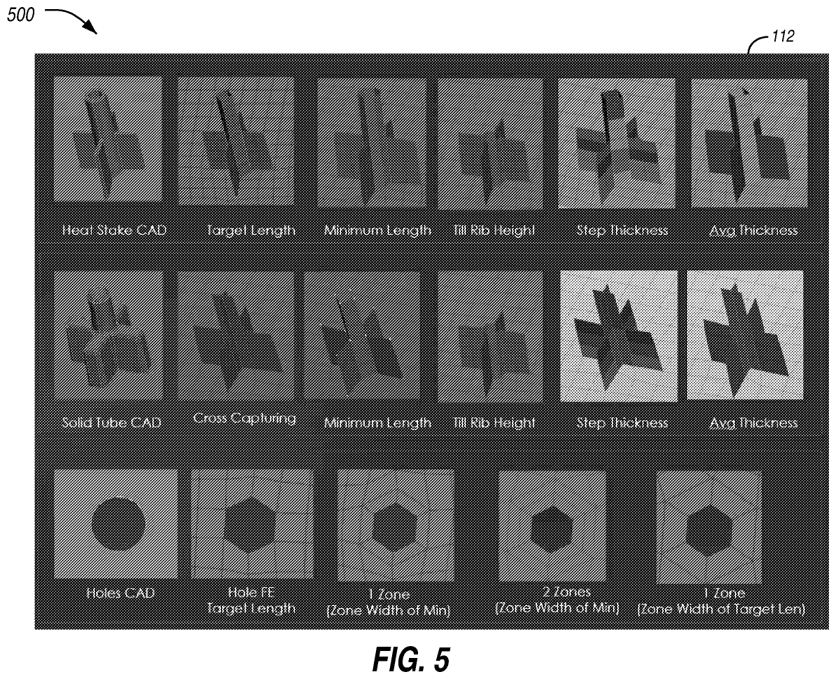

FIG. 5 illustrates an example 500 of meshes generated for three example features with different customer-specific settings 112. With respect to a heat stake identified in CAD data 104 and similarly with a solid time identified in the CAD data 104, the heat stake may be assigned meshing algorithms that relate to aspects such as target length, minimum length, and till rib height. Additionally, with respect to the modeling of thickness information, the heat stake may also be assigned meshing algorithms with respect to step thickness and average thickness of the feature. As another example, with respect to a hole identified in the CAD data 104, meshing algorithms such as hole FE target length, number of zones surrounding the hole, zone width, and target length may be specified. It should be noted that these meshing algorithms may be specified as the customer-specific settings 112, and may override base settings 230 for these values based on customer best-practices. The CAE system 106 may include a user interface through which a customer may input the customer best-practices.

FIG. 6 illustrates an example data flow diagram 600 for the generation of a mesh 214 from CAD data 104. Referring to FIG. 6, and with continuing reference to FIG. 2, a mesh plugin 234 may be utilized by the mesh generation application 216 to make use of the AI model 218 to identify features of the CAD data 104 as well as to associate feature-specific meshing algorithms 228 corresponding to the identified features with the CAD data 104 for generation of the mesh 214. For example, if the mesh plugin 234 identifies a heat stake in the CAD data 104, then the mesh plugin 234 may associate feature-specific meshing algorithms 228 for heat stakes with that identified portion of the CAD data 104.

With respect to FIG. 2, while the illustrated CAF system 106 is shown using a single computing device that incorporates the processor 202 and display device 206, other example CAE system 106 may include multiple computing devices. As one example, one processor 202 generates the AI model 218, while another processor 202 uses the AI model 218 for generation of the mesh 214 from the CAD data 104. In another nonlimiting example, the processor 202 is implemented in a server computing device that executes the mesh generation application 216 to generate the mesh 214 for a client computing device that receives the mesh 214 andlor performs simulations using the mesh 214.

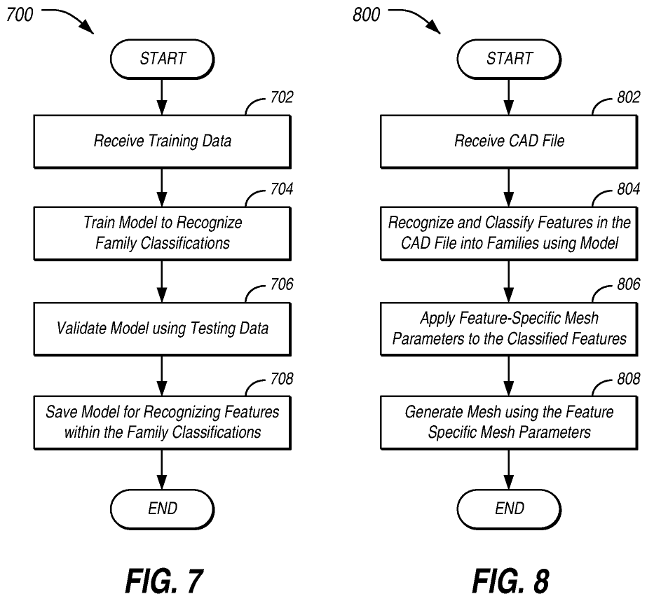

FIG. 7 illustrates an example process 700 for the generation of an AI model 218. In an example, the process 700 may be performed by aspects of the CAE system 106. For instance, the process 700 may be performed by execution of the AI training application 220 by the processor 202. As one example, the process 700 may be executed via an application programming interface or visual interface available for use by customers of the AI training application 220. As another example, the process 700 may be executed by a vendor of the AI training application 220. It should be noted that the illustrated process 700 is one example, and different operations or orderings of operations may be used.

At operation 702, the processor 202 receives training data 222. In an example, the training data 222 may include examples of features within a family received from a customer. In another example, the training data 222 may additionally or alternately include examples of features within a family received from a database of different feature designs.

The processor 202 trains the AI model 218, at 704, to recognize features within the family classification. In an example, the training data 222 may include collections of 217 views or projections of features of models, where the views are taken as renderings of sample CAD data 104 at many different angles and distances. In such an example, the processor 202 may utilize TensorFlow or another AI modeling system to train the AI model 218 to recognize the features in 2D form. In other examples, the training data 222 may be stored as CAD data 104 and may be rendered at many different angles and distances to perform the training. In yet further examples, the AI model 218 may be trained using CAD data 104 to recognize features in 3D and may be applied against 3D CAD training data 222 directly.

At 706, the processor 202 validates the AI model 218 using testing data 224. In an example, a subdivision of the training data 222 that is not used for training may be used to validate the accuracy of the AI model 218 in recognizing feature of the CAD data 104. Through use of the testing data 224, the AI training application 220 may provide training results 226, which may be used to identify weaknesses in the AI model 218 or areas in which the AI model 218 should receive additional data to improve in its recognition of features in feature families.

At operation 708, the processor 202 saves the AI model 218 for use in recognizing features within the family classification. In an example, the AI model 218 may be used as described in the process 800 for the identification of features in CAD data 104 to aid in the generation of a mesh 214 of the CAD data 104. After operation 708, the process 700 ends

FIG. 8 illustrates an example process 800 for the generation of a mesh 214 from CAD data 104 in accordance with the AI model 218. In an example, as with the process 700, the process 800 may be performed by aspects of the CAE system 106. For instance, the process 800 may be performed by execution by the processor 202 of the mesh generation application 216 and mesh plugin 234.

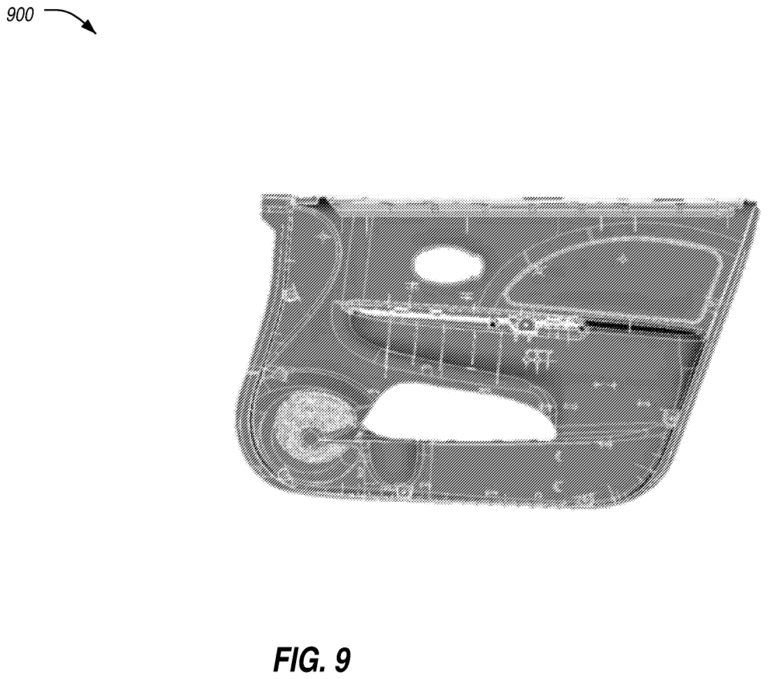

The processor 202 receives a CAD file 104 at operation 802. In an example, the CAD file 104 may be received from storage in the memory 204. In another example, the CAD file 104 may be received to the processor 202 via the network device 210 (e.g., over a network, from a CAD terminal, etc.) FIG. 9 illustrates an example 900 rendering of a CAD file 104 to be converted into a mesh 214. As shown, the CAD file 104 describes a 3D model of a plastic door panel for an automobile. It should be noted that this is only an example, and the techniques described herein may be applicable to other types of parts. For example, the CAD file 104 may represent non-plastic features such as a metal object.

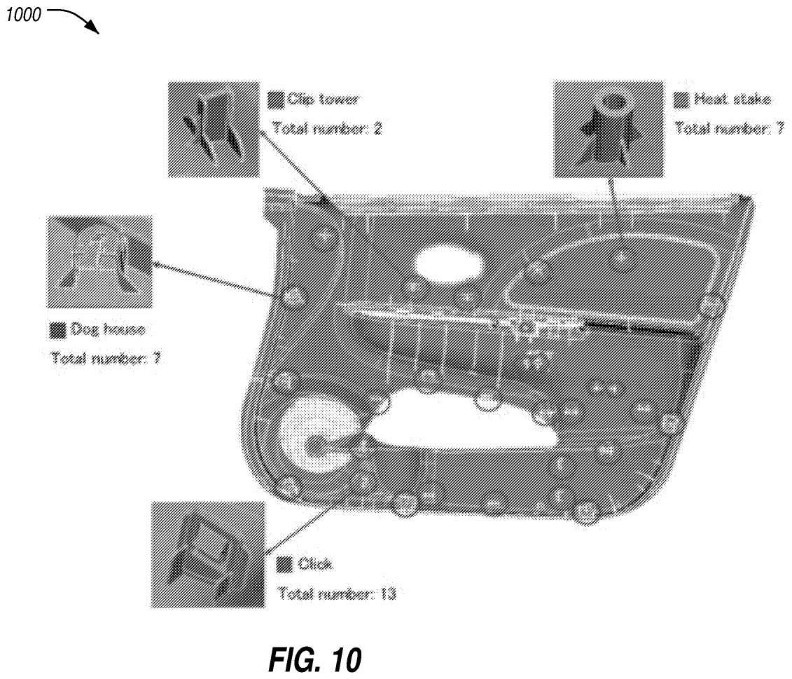

At 804, the processor 202 recognizes and classifies features in the CAD file 104 using the AI model 218. FIG. 10 illustrates an example 1000 rendering of a CAD file 104 highlighting features of the CAD file 104 recognized by the AI model 218. As shown, the processor 202 has identified seven heat stakes, two clip towers, and thirteen clicks in the 3D model described by the CAD file 104.

At operation 806, the processor 202 applies feature-specific meshing algorithms 228 to the classified features recognized at operation 604. In an example, the processor 202 identifies, for each of the identified features, the feature-specific settings 228 that correspond to that identified feature. The processor 202 may further associate those feature-specific settings 228 with the elements of the CAD file 104 that comprise the identified feature, such that the mesh 214 generation functionality of the mesh generation application 216 utilizes the associated feature-specific meshing algorithms 228 when meshing the identified feature.

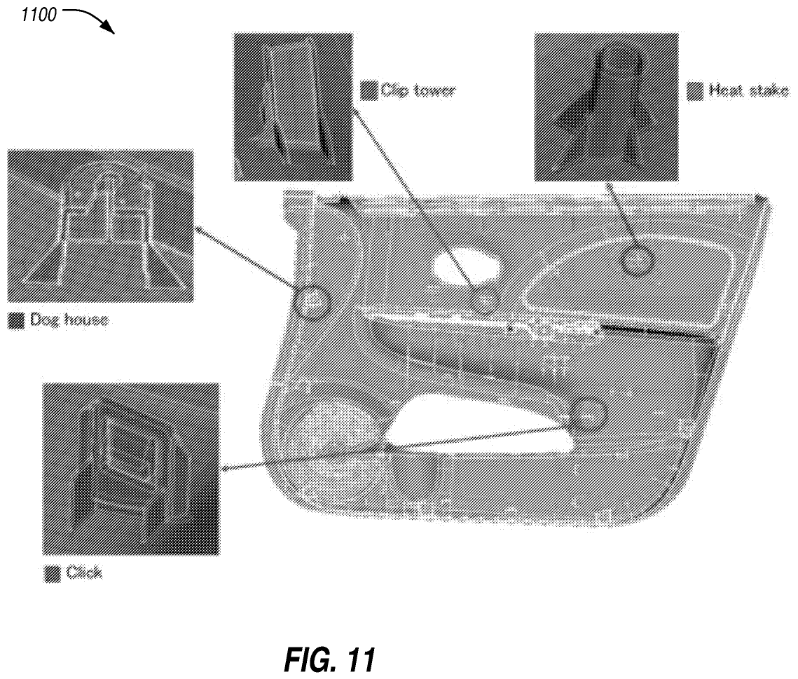

At 808, the processor 202 generates the mesh 214 using the feature-specific meshing algorithms for the recognized features. FIG. 11 illustrates an example 1100 rendering of a mesh 214 generated using feature-specific meshing algorithms for the recognized features. It should be noted that the CAE system 106 may be programmed to identify based on the generated mesh 214 whether the mesh 214 does, in fact, confirm to stipulated quality specifications. For instance, the mesh 214 may be required to meet a predefined discretization error threshold, and if the mesh 214 does not meet the error threshold, then the CAE system 106 may be programmed to made further adjustments to the mesh 214 (e.g., increase the density of polygons, etc.) to bring the mesh 214 into compliance with the error threshold.

Thus, by training an AI model 218 to recognize and classify features of the CAD file 104 based on known features within families of features and applying feature-specific meshing algorithms 228 to those identified features, a mesh 214 may be rapidly generated from the CAD file 104 that corresponds to customer-specific requirements.

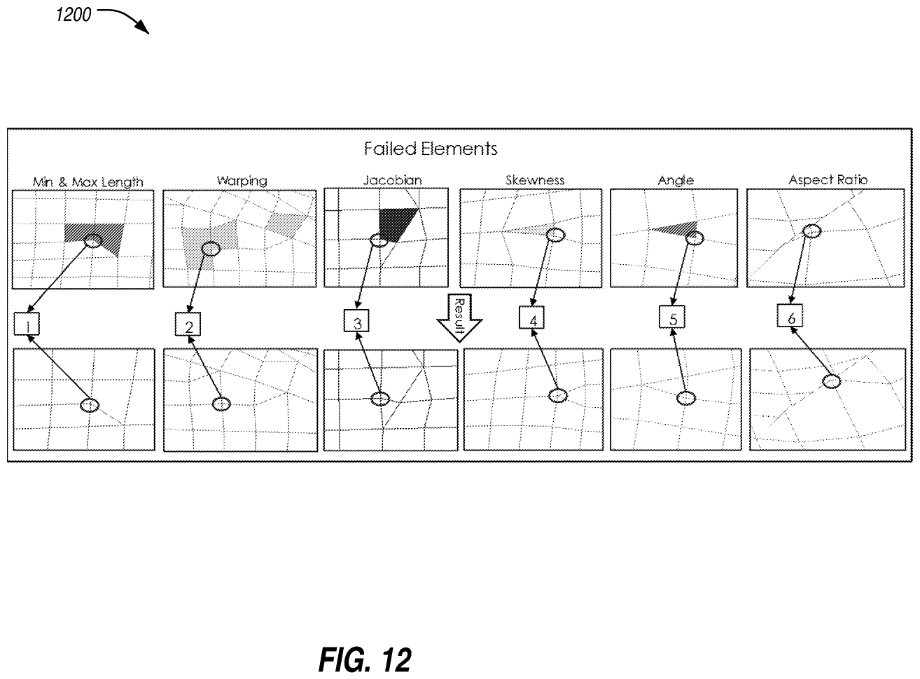

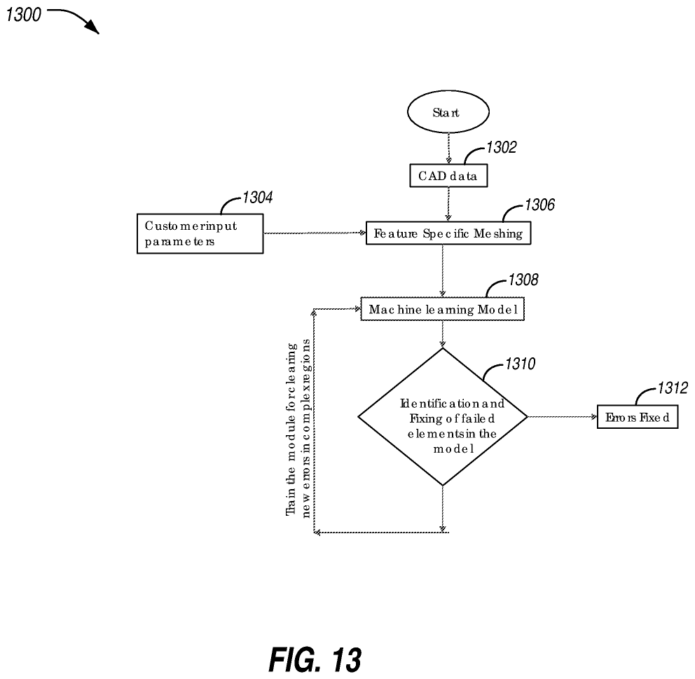

FIG. 12 illustrates an example 1200 of the automatic correction of quality specifications of the mesh 214. As shown in the examples 1200, the CAE system 106 may be programmed to automatically fix mesh quality errors in the model, such as minimum element length, warped element leads, angle or Jacobian failed elements, skewness, aspect ratio, or to minimize the number of triangular elements.

FIG. 13 illustrates an example process 1300 for the automatic correction of quality specifications of a mesh 214. In an example, the process 1300 may be performed by the elements of the CAE system 106 discussed in detail above, such as the processor 202, memory 204, mesh generation application 216, and so on. Beginning with CAD data 104 at 1302, and customer input parameters at 1304, feature specific meshing may be performed at 1306. Feature specific meshing is discussed in detail above, including with respect to the process 800. Using a machine leaning model at 1308 which is used to identify errors in the quality specifications of the mesh 214, at 1310, the processor 202 identifies and attempts to fix elements that failed to meet the quality specifications of the mesh 214. If such elements are found, the processor 202 trains the machine learning model of 1308 for clearing the new errors in the complex regions. The retraining may accordingly allow the machine learning model to identify errors which may then be fixed at 1312, such as illustrated in the example 1200.

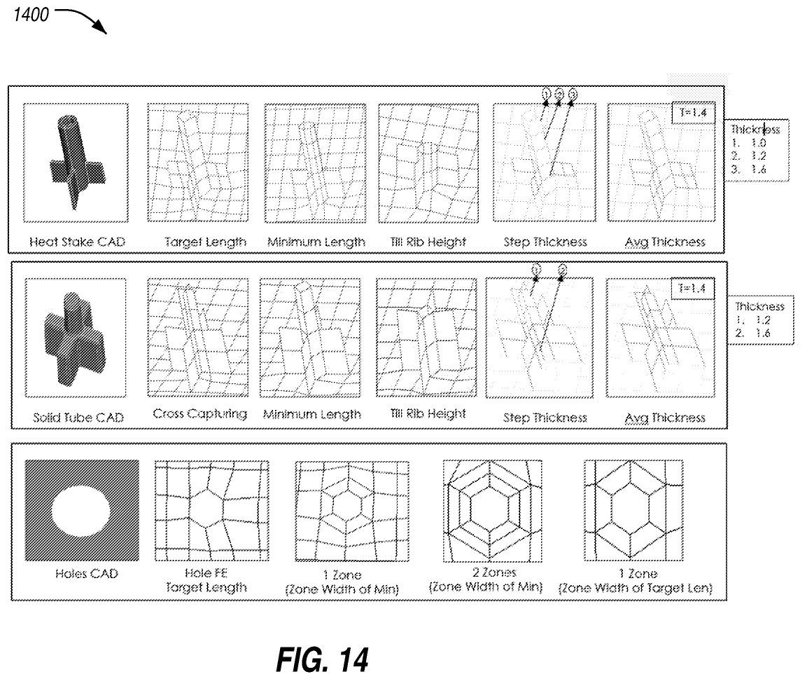

FIG. 14 illustrates an example 1400 of additional different modeling algorithms that may be used to model feature families of the CAD data 104 into the mesh 214. As mentioned above, CAE is an approximation. Modeling carefully and interpreting the results therefore becomes important for accuracy of the approximation. Base settings 230 and customer-specific settings 112 are algorithms that may be followed for modeling the specific features of the CAD data 104 based on the CAE approach as defied as base requirements or as defined by customer requirements. In addition to the examples shown in FIG. 5, the example 1400 shows additional images of features modeled with different meshing algorithms. For instance, the step thickness and average thickness are modeled for a heat stake element and also fora solid tube element. Additionally, different modelings of a hole are also shown.

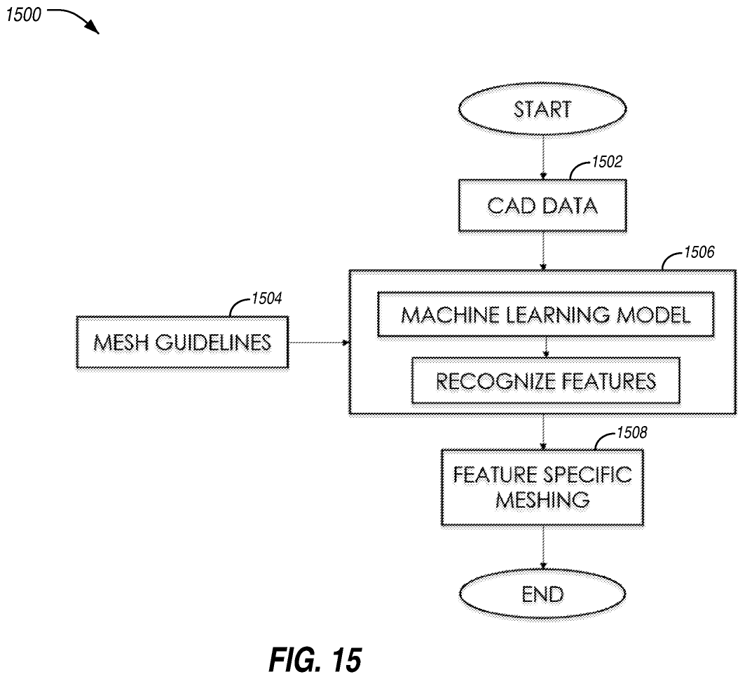

FIG. 15 illustrates an example process 1500 for the meshing of the feature families of CAD data 104 into the mesh 214. In an example, the process 1500 may be performed by the elements of the CAB system 106 discussed in detail above, such as the processor 202, memory 204, mesh generation application 216, and so on. Similar to the process 800, beginning with CAD data 104 at 1502, and using mesh guidelines at 1504 such as base settings 230 and customer-specific settings 112, at 1506 the processor 202 utilizes a machine learning model, such as the AI model 218 to recognize features of the mesh 214. The mesh guidelines may define meshing algorithms for each of the different feature families. At 1508, as discussed above including with respect to the process 800, feature specific meshing is performed to the CAD data 104 to generate the mesh 214 in accordance with the meshing algorithms as applied to the identified features per the mesh guidelines.

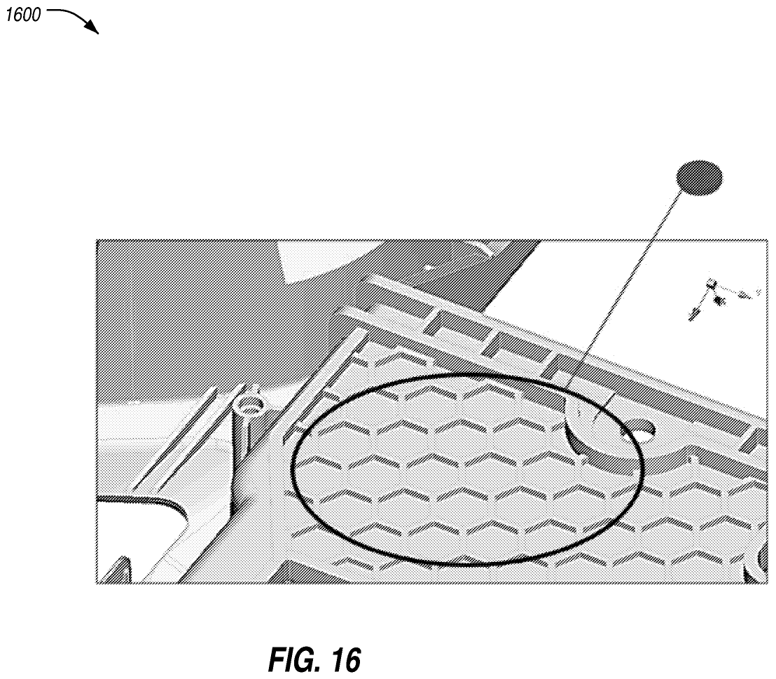

FIG. 16 illustrates an example 1600 of identifying features or parts which are not needed for a specific simulation type. This identification may be performed to ignore these aspects of the CAD data 104, so as to reduce the computational time and increase the accuracy of the simulation. For instance, the AI model 218 may be trained without regard to capture of the features or parts in the finite elements (FE) that are not required for specific simulations, such as for simulations including noise vibration harshness (NVH), crash, durability, and computational fluid dynamics (CFD).

Referring more specifically to the example 1600, honeycomb projections may be identified on the surface of the element of the CAD data 104. However, for a crash simulation or for a CFD simulation, such honeycomb projections may not be required to be captured. In contrast, for a durability simulation or for a NVH simulation, the honeycomb projections may be are included and may be necessary as they may provide stiffness to the parts.

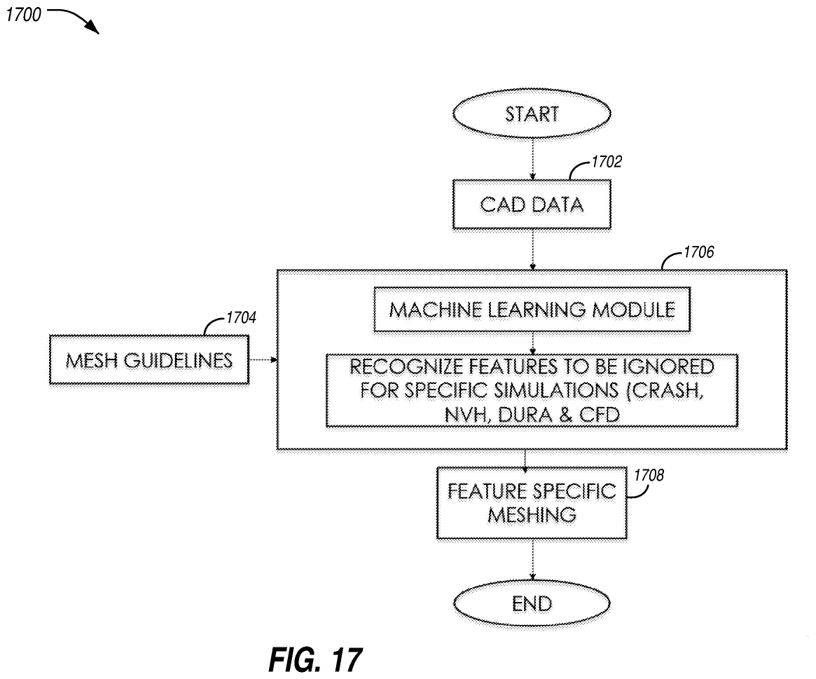

FIG. 17 illustrates an example process 1700 for the meshing of CAD data 104 into the mesh 214, while reconciling features to be ignored for the specific simulations to be performed. In an example, the process 1700 may be performed by the elements of the CAE system 106 discussed in detail above, such as the processor 202, memory 204, mesh generation application 216, and so on. Similar to the processes 800 and 1500, beginning with CAD data 104 at 1702, and using mesh guidelines at 1704 such as base settings 230 and customer-specific settings 112, at 1706 the processor 202 utilizes a machine learning model, such as the AI model 218 to recognize features of the mesh 214. However, here the AI model 218 may be used to recognize features to be ignored for the specific simulations to be run, such as discussed with respect to the example 1600. For instance, the process 1700 may receive input indicative of the intended simulations to run with the mesh 214 to be generated. At 1708, feature specific meshing is performed to the CAD data 104 to generate the mesh 214 in accordance with the meshing algorithms as applied to the identified features per the mesh guidelines, but while ignoring the features that are not required for the specific simulations being run.

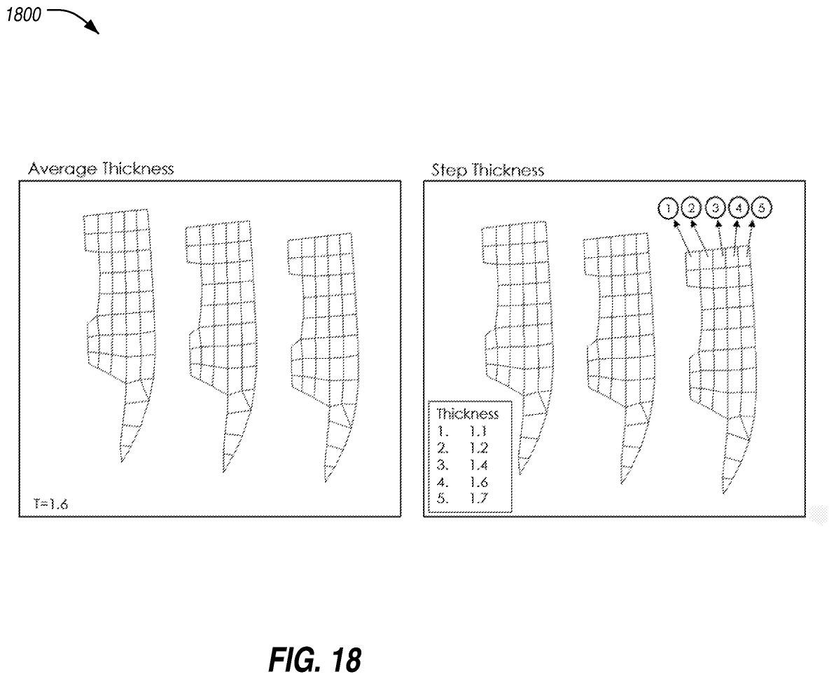

FIG. 18 illustrates an example 1800 of thickness assignment performed using the CAE system 106. As noted herein, finite element analysis is an approximation process. In one example, to save the computational time, the CAD data 104 FE elements may be captured mid-plane. To allow for thickness information, the 3d structure of the CAD data 104 may be denoted in the mesh 214 by thickness data, which is calculated and assigned to the FE elements. The example 1800 shows both average thickness information, e.g., with thickness of 1.6 mm, as well as step thickness of the mesh, with thicknesses that step from 1.1, to 1.2, to 1.4, to 1.6, and to 1.7 mm.

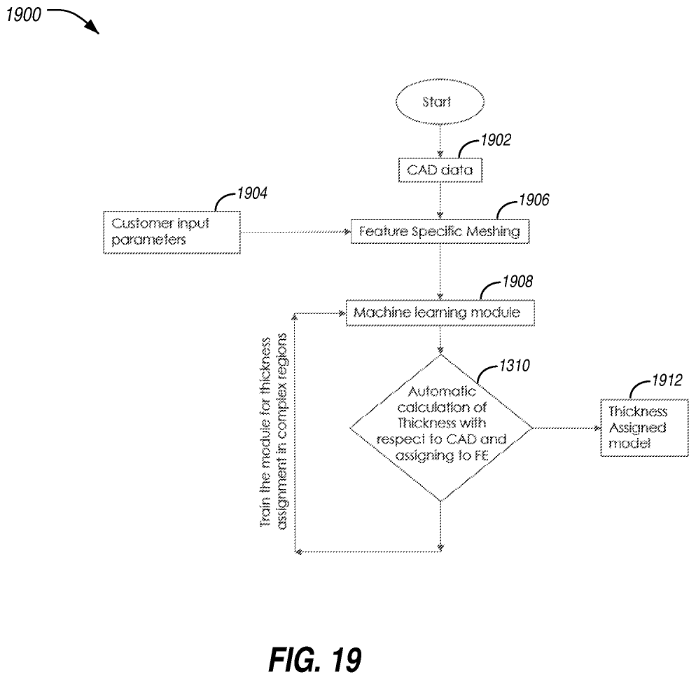

FIG. 19 illustrates an example process 1900 for the automatic calculation of thickness for assignment to finite element of a mesh generated from CAD data 104. In an example, the process 1900 may be performed by the elements of the CAE system 106 discussed in detail above, such as the processor 202, memory 204, mesh generation application 216, and so on. Beginning with CAD data 104 at 1902, and customer input parameters at 1904, feature specific meshing may be performed at 1906. Feature specific meshing is discussed in detail above, including with respect to the process 800. Using a machine leaning model at 1908 which is trained for thickness assignment of mid-plane mesh 214 data, at 1910, the processor 202 performs automatic calculation of mesh 214 thickness with respect to the CAD data 104 for assignment to the finite elements of the mesh 214. If such finite elements are found, the processor 202 trains the machine learning model of 1908 for assigning the new thicknesses in the complex regions. The retraining may accordingly allow the machine learning model to better identify thicknesses and regions onto which the thicknesses may be assigned. The thicknesses may then be applied at 1912, such as illustrated in the example 180.

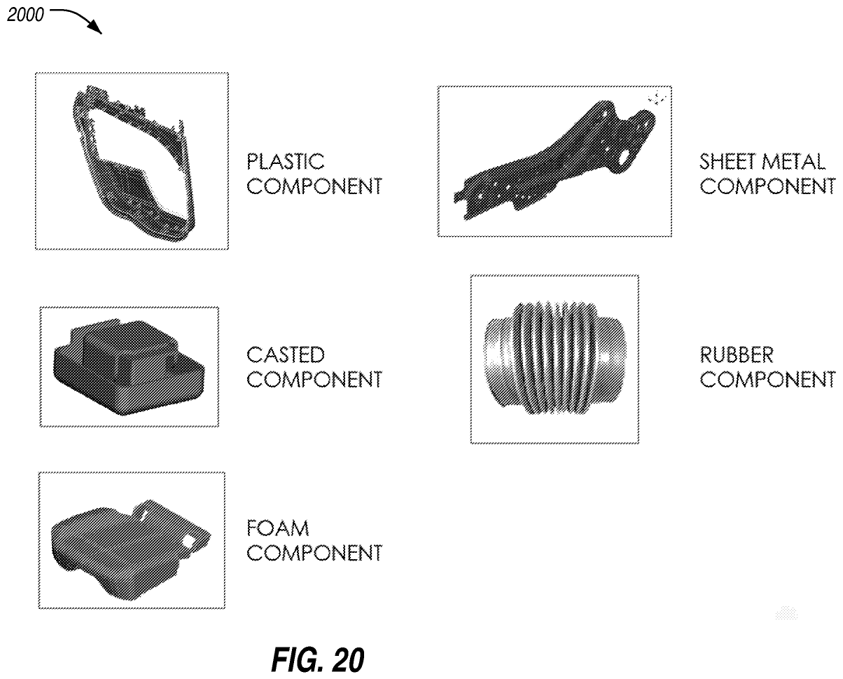

FIG. 20 illustrates an example 2000 of components of different materials or manufacturing processes that may be converted into meshes 214. While many examples herein relate to plastic features such as heat stakes, clip towers, dog houses, or click fasteners, the systems and methods described herein may identify elements made from different materials as well, such as metals or rubber components. Moreover, the identified features may be generated by different manufacturing processes including forming, molding, extrusion, casting, forming, forging. Moreover, these different manufacturing processes andor materials may be modeled with guidelines specific to the manufacturing process and/or material. This may be done, in an example, through use of meshing algorithms that are tailored to the specific manufacturing processes and/or materials. In some example the AI model 218 may be trained to identify the different components by manufacturing processes and/or materials as well, to facilitate the assignment of meshing algorithms by process and/or by material, instead of or in addition to by feature.

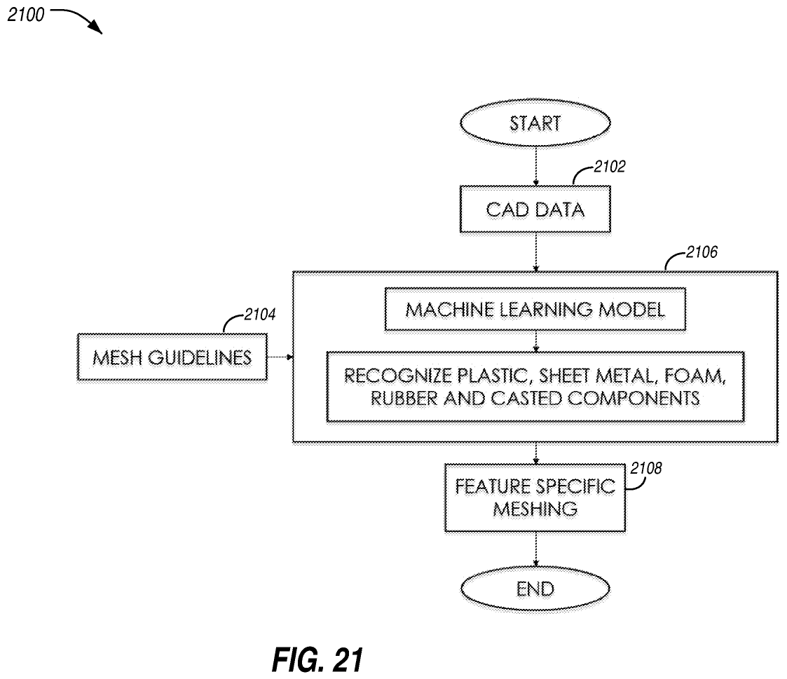

FIG. 21 illustrates an example process 2100 for the meshing of CAD data 104 into the mesh 214, while applying meshing algorithms according to material or manufacturing process. In an example, the process 2100 may be performed by the elements of the CAE system 106 discussed in detail above, such as the processor 202, memory 204, mesh generation application 216, and so on. Similar to the processes 800,1500 and 1700, beginning with CAD data 104 at 2102, and using mesh guidelines at 2104 such as base settings 230 and customer-specific settings 112, at 2106 the processor 202 utilizes a machine learning model, such as the AI model 218 to recognize features of the mesh 214. However, here the AI model 218 may be used to recognize features according to manufacturing processes and/or materials, such as discussed with respect to the example 2000. At 2108, feature specific meshing is performed to the CAD data 104 to generate the mesh 214 in accordance with the meshing algorithms as applied to the identified features for the respective manufkturing processes and/or materials per the mesh guidelines.

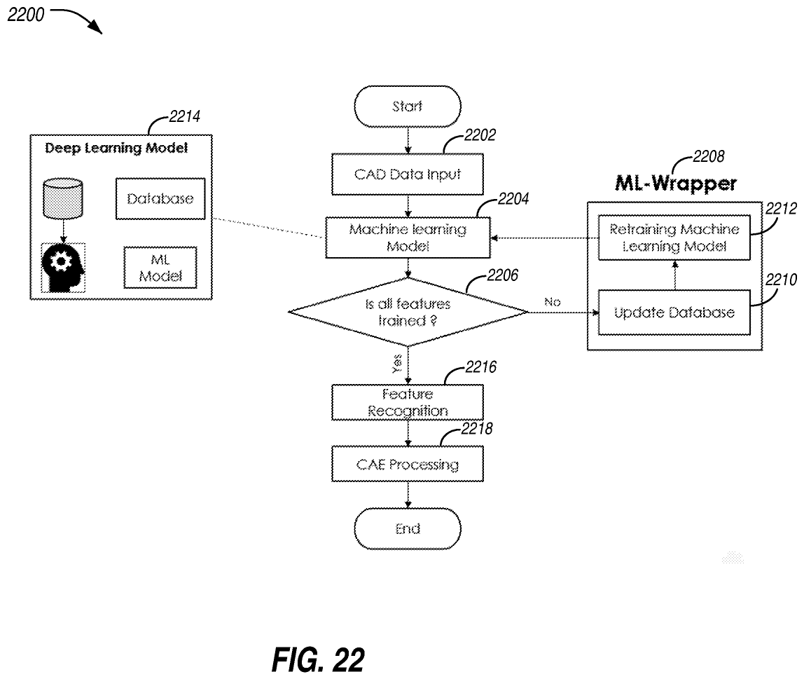

FIG. 22 illustrates an example process 2200 for the retraining and use of an updated AI model 218 for feature recognition and meshing. In an example, the process 2200 may be performed by the elements of the CAE system 106 discussed in detail above, such as the processor 202, memory 204, mesh generation application 216, and so on. At 2202, with CAD data 104 may be input or received, which may be applied to a machine learning model at 2204. If, at 2206, not all of the features of the CAD data 104 are recognized using the model, then the processor 202 may determine that not all features of the model have been trained. If so, control passes to a machine learning wrapper 2208 to update the feature database 116 at 2210 to include examples (or additional examples) of the features that were not recognized. The machine learning wrapper 2208 may be accessed by a customer to add customer-specific features to a customer-specific feature database 116 in one example, but in other examples, the features may be added to a feature database 116 that is shared across customers or sites. Regardless, these examples may take the form of 2D views of the features as discussed in detail above. Next, at operation 2212 the processor 202 may retain the AI model 218 according to the updated features in the feature database 116. The AI model 218 may be a deep-learning model 2214 as shown, generated using deep learning techniques according to the features included in the feature database 116. Once retrained, control may return to operation 2204 to again attempt to recognize the features of the CAD data 104. If all the features are trained at 2206, then feature recognition is performed at 2216, and CAE processing, such as meshing and simulation, is performed by the processor 202 at operation 2218. Thus, the machine learning wrapper 2208 may be used to add new feature classes into the AI model 218 and may collect raw data for this new feature class and help retrain the AI model 218. The newly trained model may then be used for recognizing corresponding new features in the CAD models 104.

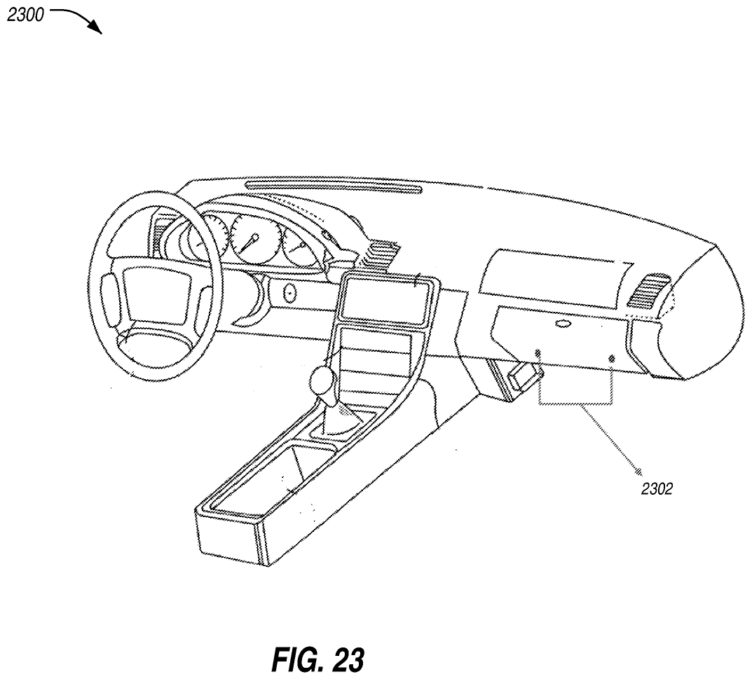

FIG. 23 illustrates an example 2300 of identifying part assemblies from CAD data 104. In an example, the processor 202 may be programmed to automatically recognize different physical parts for creating sensor or boundary conditions for different model types. This may be advantageous, as manual identification of the specific areas where the sensor or the boundary conditions for CAE are to be incorporated may be time consuming to implement. As shown in the example 2300, sub-assemblies such as the instrument panel, console, and steering assembly may be included in a vehicular assembly. As shown at 2303, parts such as a glove box portion of the instrument panel assembly may be identified for simulations, such as for knee-impact analysis. The CAE system 106 may accordingly locate and create accelerometer in the correct locations for use in occupant safety simulations. As one more specific example, the CAE system 106 may infer that the vehicle components in the CAD data 104 relate to a station wagon and may place the sensors in locations consistent with those used for station wagon testing. As another example, the CAE system 106 may infer that the vehicle components in the CAD data 104 relate to a convertible vehicle and may place the sensors in locations consistent with those used for convertible vehicle testing.

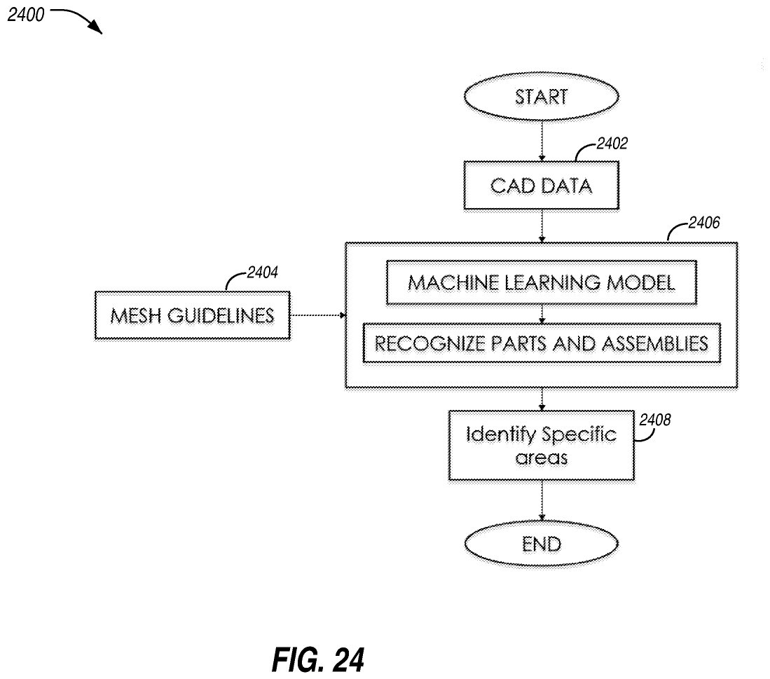

FIG. 24 illustrates an example process 2400 for the meshing of CAD data 104 into the mesh 214, while identifying locations for sensor placement. In an example, the process 2400 may be performed by the elements of the CAE system 106 discussed in detail above, such as the processor 202, memory 204, mesh generation application 216, and so on. Beginning with CAD data 104 at 2402, and using mesh guidelines at 2404 such as base settings 230 and customer-specific settings 112 at 2404, at 2406 the processor 202 utilizes a machine learning model, such as the AI model 218 to recognize features of the mesh 214. However, here the AI model 218 may be used to recognize parts and assemblies in the CAD data 104 for determining specific areas to apply sensors, such as discussed with respect to the example 2300. At 2408, identification of the specific areas in the CAD data 104 is performed based on the use of the machine learning model. Accordingly, sensor positions for the CAD data 104 may be quickly and automatically applied, which may be useful in meshing and simulation of the mesh 214 at the proper identified sensor locations.

The processes, methods, or algorithms disclosed herein can be deliverable to-implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A system for generating a finite element mesh, comprising:
a memory configured to store a representation of geometric features of an object, a machine learning model configured to identify one or more feature families of features of the representation, and feature-specific meshing algorithms defining how to mesh the one or more feature families; and
a processor programmed to
recognize and classify features of the representation into the feature families utilizing the machine learning model,
identify feature-specific meshing algorithms defined in accordance with stipulated specifications and best practices,
apply the feature specific meshing algorithms to the recognized and classified features of the representation, and
generate a mesh of the representation in accordance with the identified feature-specific meshing algorithms.

2. The system of claim 1, wherein the feature families include one or more of: heat stakes, clip towers, dog houses, click fastener elements, nuts, bolts, molded rubber components, bushings, sleeves, seals, mounts, or bellows.

3. The system of claim 1, wherein the representation is a computer-aided design (CAD) file received as input from a computer-aided design (CAD) system.

4. The system of claim 1, wherein the processor is further programmed to train the machine learning, model to recognize and classify features of the representation utilizing training data including example features within the families of features.

5. The system of claim 4, wherein the training data includes a plurality of 2D views of the example features, and to recognize and classify features of the representation includes to recognize the features on a 2D view of the representation.

6. The system of claim 4, wherein the processor is further programmed to validate the machine learning model using testing data, wherein the testing data is a subdivision of the training data that is not used for training of the machine learning model.

7. The system of claim 4, wherein the processor is further programmed to expose an interface through which the training the machine learning model may be invoked.

8. The system of claim 1, wherein the processors further programmed to train the machine learning model to recognize and classify features in the representation of components designed from materials including: metal, plastics, or rubber, and wherein the components are designed to be generated by manufacturing processes including: forming, molding, extrusion, casting, forming, or forging.

9. The system of claim 1, wherein the best practices are defined by a customer, and the processor is further programmed to utilize the best practices of the customer to override default system settings when generating a mesh for the customer.

10. The system of claim 1, wherein the processor is further programmed to assign nodal and element thicknesses to the mesh in accordance with the identified feature-specific meshing algorithms such that thicknesses defined by the representation are interpolated onto the mesh.

11. The system of claim 1, wherein the processor is further programmed to:
infer a model type according to a recognition of parts of the CAD data; and
assign sensor locations to the CAD data in accordance with the model type.

12. The system of claim 1, wherein the processor is further programmed to generate a bill of materials listing each part included in the CAD data.

13. The system of claim 1, wherein the processor is further programmed to recognize deviations between the representation and an image of a manufactured part defined by the representation by recognizing the features of the image using the AI model and determining variances between the image and the mesh.

14. A method comprising:
storing, to a memory, a representation of geometric features of an object, a machine learning model configured to identify one or more feature families of features of the representation, and feature-specific parameters defining how to mesh the one or more feature families;
recognizing and classifying features of the representation into the feature families utilizing the machine learning model;
identifying feature-specific meshing algorithms defined in accordance with stipulated specifications and best practices for the feature families;
applying the feature-specific meshing algorithms to the recognized and classified features of the representation; and
generating a mesh of the representation in accordance with the identified feature-specific meshing algorithms.

15. The method of claim 14, wherein the feature families include one or more of: heat stakes, clip towers, dog houses, or click fastener elements.

16. The method of claim 14, wherein the representation is a computer-aided design (CAD) file.

17. The method of claim 14, further comprising training the machine learning model to recognize and classify features of the representation utilizing training data including example features within the families of features.

18. The method of claim 17, wherein the training data includes a plurality of 2D views of the example features, further comprising recognizing the features on a 2D view of the representation.

19. The method of claim 17, further comprising validating the machine learning model using testing data, wherein the testing data is a subdivision of the training data that is not used for training of the machine learning model.

20. A non-transitory computer-readable medium comprising instructions that when executed by a processor, cause the processor to:
store, to a memory, a representation of geometric features of an object, a machine learning model configured to identify one or more feature families of features of the representation, and feature-specific parameters defining how to mesh the one or more feature families;
recognize and classify features of the representation into the feature families utilizing the machine learning model;
identify feature-specific meshing algorithms defined in accordance with stipulated specifications and best practices for the feature families;
apply the feature-specific meshing algorithms to the recognized and classified features of the representation; and
generate a mesh of the representation in accordance with the identified feature-specific meshing algorithms.

21. The medium of claim 20, wherein the feature families include one or more of: heat stakes, clip towers, dog houses, or click fastener elements.

22. The medium of claim 20, wherein the representation is a computer-aided design (CAD) file.

23. The medium of claim 20, further comprising instructions that, when executed by a processor, cause the processor to train the machine learning model to recognize and classify features of the representation utilizing training data including example features within the families of features.

24. The medium of claim 23, wherein the training data includes a plurality of 2D views of the example features, and further comprising instructions that, when executed by a processor, cause the processor to recognize the features on a 2D view of the representation.

25. The medium of claim 23, fitrther comprising instructions that, when executed by a processor, cause the processor to validate the machine learning model using testing data, wherein the testing data is a subdivision of the training data that is not used for training of the machine learning model.
